(19) United States
(12) Patent Application Publication
(10) Pub. No.: US 2019/0074776 A1
(43) Pub. Date: Mar. 7, 2019

(54) Dynamic System Resonant Frequency Detection and Compensation Methods for WPT and Relevant Technologies

(71) Applicant: Jianlong TIAN, Langfang City (CN)

(72) Inventor: Jianlong TIAN, Langfang City (CN)

(73) Assignee: Jianlong TIAN, Langfang City (NZ)

(21) Appl. No.: 16/083,491

(22) PCT Filed: Apr. 6, 2017
(86) PCT No.: PCT/CN2017/079538

§ 371 Date: Oct. 1, 2018

(30) Foreign Application Priority Data
Apr. 6, 2016 (NZ) 718749

(51) Int. Cl. H02M 7/48; G01R 25/00; H03J 1/06; H03J 1/18; H02J 50/12

(52) U.S. Cl. CPC H02M 7/48; G01R 25/00; H02M 2007/4818; H03J 1/18; H02J 50/12; H03J 1/06

(57) ABSTRACT

A switch mode DC-AC converter driven oscillation system which always works on square wave driving, soft-switching and resonant conditions supported by the following techniques is disclosed. \textcircled{1} the techniques composed of totally analog circuitry to dynamically detect the innate resonant frequency of the system through comparison between the phases of the gate driving and zero voltage or current crossing signals of the main oscillation of the system and to drive the system with the detected innate resonant frequency to realize resonant operation and soft-switching. Based on different types of PLL technologies, two of such techniques are disclosed. \textcircled{2} the technique to realize a Voltage Controlled Soft-switching Capacitor (VCSC) to compensate the innate resonant frequency or to adjust the output voltage or power of the system through its tuning/detuning effect. The disclosed techniques can be combined to realize “square wave driving, soft-switching and resonant” systems which operate in either variable or fixed frequency conditions.

### FIELD

This invention relates generally to dynamic resonant frequency detection and compensation methods for switch mode DC-AC converter driven oscillation systems, for example Wireless Power Transfer (WPT) systems, switch mode power supplies, etc. With the techniques proposed in this patent, these systems can be made always work on “square wave driving, soft-switching and resonant” conditions at the same time so that the efficiency and power transfer ability of these systems can be optimized, or the output voltage can be adjusted or stabilized with high efficiency within a large range by tuning/detuning.

### BACKGROUND

In some way, a WPT system is an oscillation system. Energy is transferred through oscillation. Without oscillation, there will be no power transfer. To transfer power well, the system needs to oscillate well first. For the system to oscillate well, the innate resonant frequency of the system needs to be known so that the system can be driven with its innate resonant frequency to realize soft-switching and resonance to maximize the power transfer ability and efficiency. However, the innate resonant frequency of a WPT system is not constant but changes with many factors of the system such as the coupling coefficient between the primary and secondary side, the variation of the load and many other parameters of the circuit. As a matter of fact, frequency is the most important factor of a WPT system which influences almost every important aspect of the system such as resonance, soft-switching, power transfer ability and efficiency, etc. Once the frequency of the system is properly under control, every important aspect of the system will be under control. So it is important to have a method to monitor the ever-changing system resonant frequency in real time.

Besides, WPT systems are usually driven by switch mode DC-AC converters. From a certain point of view, a WPT system is a switch mode DC-AC converter driven oscillation system. For switch mode DC-AC converters, “square wave driving and soft-switching” are important for the converter to maintain high efficiency. Especially at high frequency or high power conditions, “soft-switching or not” may mean whether the system can operate normally or not because in these situations, the high power loss in non-soft-switching switches can lead to the failure of the switches.

In summary, for a WPT system (a switch mode DC-AC converter driven oscillation system), it is very important to realize “square wave driving, soft-switching and resonance” at the same time by driving the system with its innate resonant frequency for the system to maintain high efficiency and high power transfer ability. This patent proposes a series of techniques to detect and compensate the innate system resonant frequency to guarantee the system always work on the above three essential conditions at the same time to maximize the power transfer ability and efficiency of the system. The description of these techniques and their applications is divided into three parts and organized as follows in the “DETAILED DESCRIPTION OF EMBODIMENTS OF THE INVENTION” section.
1) Dynamic system resonant frequency detection methods
2) System resonant frequency compensation methods
3) Multi-transmitters high power WPT systems

### SUMMARY

This patent proposes a series of techniques to guarantee switch mode DC-AC converter driven oscillation systems always work in “square wave driving, soft-switching and resonant” conditions at the same time, which is very important for maximizing the efficiency and power transfer ability of such systems. So far as is known, there is still no technique which can realize these three goals at the same time.

The most important of this series of techniques is the one to dynamically detect the innate system resonant frequency in real time, making the system driving and innate resonant frequencies equal to each other while maintaining soft-switching and square wave driving for the switch mode DC-AC converter of the system. The second one is the Voltage Controlled Soft-switching Capacitor (VCSC), which can be used at the primary side of the system for compensating the innate system resonant frequency to make this frequency constant or used at the secondary side of the system for adjusting or stabilizing the output voltage through the tuning/detuning effect. There are still two supporting techniques for the above two main techniques to work normally or better. One is the frequency bifurcation avoiding technique. The other is the technique to control the output pulse width of mono-stable flip flops (or multivibrators) with a DC voltage.

With these techniques available, either fixed or variable frequency operation can be realized for switch mode DC-AC converter driven oscillation systems and the systems will always work on “square wave driving, soft-switching and resonant” conditions at the same time, which is the guarantee of the maximization of the system efficiency and power transfer ability. Furthermore, the availability of these techniques makes possible the strategy to drive the same secondary side circuit of a WPT (Wireless Power Transfer) system with modelled multi-primary side transmitters, which is also suggested in this patent. Finally, the application of these techniques is not limited to WPT systems. They can be used at any power electronic systems where switch mode DC-AC conversion is needed such as switch mode power supplies, DC-DC converters, HVDC (High Voltage Direct Current) power transmissions, etc.

### BRIEF DESCRIPTION OF THE DRAWINGS

The accompanying drawings which are incorporated in and constitute part of the specification, illustrate embodiments of the invention and, together with the general and detailed descriptions of the invention given above and below, serve to explain the principles of the invention.

FIG. 1 shows a circuit diagram of detecting the innate system resonant frequency using PC1.

FIG. 2 shows a circuit diagram of detecting the innate system resonant frequency using PC2.

FIG. 3 shows a circuit diagram of the structure of the VCSC.

FIG. 4 shows a graph of the simulated waveforms of the VCSC.

FIG. 5 shows a circuit diagram of the methods to generate the controlling signal for the VCSC.

FIG. 6 shows a circuit diagram of using the VCSC and Controller 1 or 2 to form a fixed frequency and resonant WPT system.

FIG. 7 shows a circuit diagram of the parallel tuning/detuning method to stabilize the output voltage of a WPT system through the VCSC.

FIG. 8 shows a circuit diagram of the serial tuning/detuning method to stabilize the output voltage of a WPT system through the VCSC.

FIG. 9 shows a circuit diagram of the configuration of the Multi-transmitters strategy.

### DETAILED DESCRIPTION OF EMBODIMENTS OF THE INVENTION

This part includes the following three sections:
1) Dynamic system resonant frequency detection methods
2) System resonant frequency compensation methods
3) Multi-transmitters high power WPT systems

### 1. Dynamic System Resonant Frequency Detection Methods

1.1 Introduction

To detect the innate resonant frequency of WPT systems, PLL (Phase Locked Loop) technology is used in this patent to compare the phase difference between the gate driving signal and the detected ZVC (Zero Voltage Crossing) or ZCC (Zero Current Crossing) signal of the main oscillation in the resonant tank of the WPT system. A key point which needs to be emphasized is that what is compared directly in this patent is not the frequency of the two input signals of the PC (Phase Comparator) in the PLL chip but the phase of the two input signals of the PC. This is because the detected frequency of the main oscillation of the system always equal to the driving frequency of the system. So there is no need to compare them. However, for WPT systems, as long as the driving frequency does not equal to the innate resonant frequency of the system, there will exist a phase difference between the gate driving signal and the detected ZVC or ZCC signal so that it is not be ZVS (Zero Voltage Switching) or ZCS (Zero Current Switching). By comparing the phase difference between the gate driving signal and the detected ZVC or ZCC signal, the difference between the driving frequency and the innate resonant frequency of the system can be found. In other words, the phase difference between the gate driving signal and the detected ZVC or ZCC signal reflects the difference between the driving frequency and the innate resonant frequency of the system. So by detecting the phase difference between the gate driving signal and the detected ZVC or ZCC signal and making them to be the same (so that there is no phase difference between them and the switch mode DC-AC converters of the system works on soft-switching condition at the moment) through changing the driving frequency or compensating the innate system resonant frequency, the driving frequency and the innate resonant frequency of the system can be made to be the same so that resonant operation (and soft-switching and square wave driving at the same time for the DC-AC converter of the system) can be realized for the system finally.

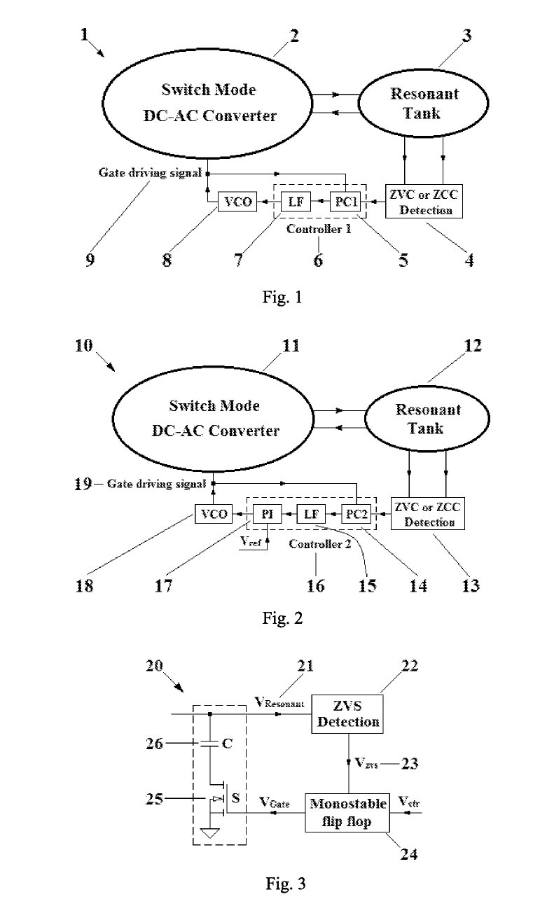

According to whether phase difference exists between its two input signals at locked condition, the PC (Phase Comparator) used in this patent are divided into two categories, i.e. PC1 (no phase difference exists at locked condition) and PC2 (there exists phase difference between its two input signals at locked condition) as shown in FIG. 1 and FIG. 2 in the next section, respectively.

Please note that the methods proposed in this patent apply to any kind switch mode DC-AC converters except for autonomous push pull converters which are not driven by square waves generated by professional gate drivers.

1.2 PC1 (No Phase Difference Exists at Locked Condition)

FIG. 1 shows the technique to detect the system resonant frequency to realize soft-switching and resonance using PC1. As mentioned above, to realize soft-switching and resonance, the driving frequency of the converter needs to equal the innate system resonant frequency. However, the innate system resonant frequency cannot be detected directly when the system is forced to oscillate at the gate driving frequency. Therefore, instead of detecting the innate system resonant frequency directly, a PC is employed to compare the phase differences between the gate driving signal 9 and the detected ZVC or ZCC signal 4 as shown in FIG. 1.

As mention in the introduction part, as long as the driving frequency of the system does not equal to the innate resonant frequency of the system, there will be a phase difference between the above two signals. So by detecting the phase difference between the above two signals, the difference between the system driving frequency and the system innate resonant frequency can be known, and by making the phase difference between the above two signals to be zero, the driving frequency of the system can be made equal to the innate resonant frequency of the system so that “square wave driving, soft-switching and resonance” can be realized at the same time. In FIG. 1, the phase difference between the gate driving signal 9 and the detected ZVC or ZCC signal 4 is made to be zero by changing the output frequency (the gate driving frequency of the system 9) of the VCO 8 through the variation of the output voltage of the LF (Low-pass Filter) 7. It is one of the features of the PC1 that the output voltage of the LF 7 and the output frequency of the VCO will change until the phase difference between its input signals become zero, so finally the system driving frequency 9 becomes equal to the ZVS or ZCS frequency of the system.

Please note that the part of the circuit in the dashed block in FIG. 1 (including LF and PC1) is defined as “Controller 1” 6 in this patent.

1.3 PC2 (there Exists Phase Difference Between the Two Input Signals at Locked Condition)

FIG. 2 shows the technique to detect the system resonant frequency to realize soft-switching and resonance using PC2. The only difference between this method and the one using PC1 is that a PI (Proportional plus Integral) controller 17 is inserted between the VCO 18 and the LF 15 as shown in FIG. 2. The reason why a PI controller is inserted is that PC2 (14) itself cannot guarantee the phase difference between its two input signals to be zero (or a preset fixed value, for example 180° out of phase, but the switch mode DC-AC converter of the system works on soft-switching condition at the moment) at locked condition, which however is the final purpose of the controller. To solve this problem, a PI controller 17 is inserted. The reference voltage V_{ref} of the PI controller 17 equals to the output voltage of the LF 15 when the phase difference between the two input signals of the PC2 is zero (or the preset fixed value, for example 180° out of phase, but the switch mode DC-AC converter of the system works on soft-switching condition at the moment). When the phase difference between the two input signals of the PC2 is not zero (or not the preset fixed value), the output voltage of the LF does not equal to the reference voltage V_{ref} of the PI controller, so the output voltage of the PI controller 17 varies to change the output frequency 19 of the VCO until this frequency 19 equals to the innate system resonant frequency so that the phase difference between the two input signals of the PC2 is zero (or the preset fixed value, for example 180° out of phase, but the switch mode DC-AC converter of the system works on soft-switching condition at the moment). This is the basic operating principle of the technique using PC2 (14).

Please note that the part of the circuit in the dashed block in FIG. 2 (including PI, LF and PC2) is defined as “Controller 2” 16 in this patent.

1.4 A Method to Avoid Bifurcation

Both of the two methods proposed in Section 1.2 and Section 1.3 lead to variable frequency systems. One problem with variable frequency WPT systems is that the frequency of the system tends to bifurcate sometimes. When bifurcation occurs, the frequency of the system jumps suddenly from one value to the other, and usually there is a large difference between the values of these two frequencies. For example, when one is a few hundred kHz, the other can be a few MHz. To avoid bifurcation, this patent suggests limiting the output frequency of the VCO to the normal operating range of the system in some way to avoid jumping. For example, this can be realized by selecting proper values for the external resistors and/or capacitors of the VCO, or using some voltage dividers formed by resistors to limit the range of the input controlling voltage of the VCO, etc.

### 2. System Resonant Frequency Compensation Methods

2.1 The Voltage Controlled Soft-Switching Capacitor (VCSC)

The techniques presented above are to change the system driving frequency to follow the innate system resonant frequency so that a variable frequency system is obtained finally. To form a fixed frequency and resonant system, means to compensate the changing system resonant frequency to make it constant is needed. This patent proposes a Voltage Controlled Soft-switching Capacitor (VCSC) for this purpose as shown in FIG. 3.

Please note that the capacitor C 26 and the switch S 25 in FIG. 3 can also be in parallel in certain situations in the circuit. Those skilled in the art can find any number of variations. It is not the intention of the applicant to restrict or in any way limit the invention to the specific details. In fact, there is nothing new in the circuit structure itself. The point is how to operate it, i.e. how to realize soft-switching for the switch S 25 in the VCSC 20. This patent suggests making S 25 turn on when the resonant voltage V_{Resonant} 21 is zero and off when the resonant voltage V_{Resonant} 21 is not zero. By controlling the conduction period of the capacitor C 26 or the moment the switch S 25 is turned off, the average equivalent capacitance of the VCSC 20 can be adjusted. This is the basic operating principle of the VCSC. The fact is that if the switch S 25 is turned on suddenly when the resonant voltage V_{Resonant} 21 is not zero, it is a big problem because the main oscillation V_{Resonant} 21 will be seriously distorted in this case. However, if S 25 is turned off suddenly when the resonant voltage V_{Resonant} 21 is not zero, it is not much problem because the main oscillation can go on smoothly with almost no distortion in this case. It is soft-switching when S 25 turns on because the resonant voltage V_{Resonant} 21 is zero at the moment. It can be regarded as quasi-soft-switching when S 25 is turned off as long as it is turned off quickly enough.

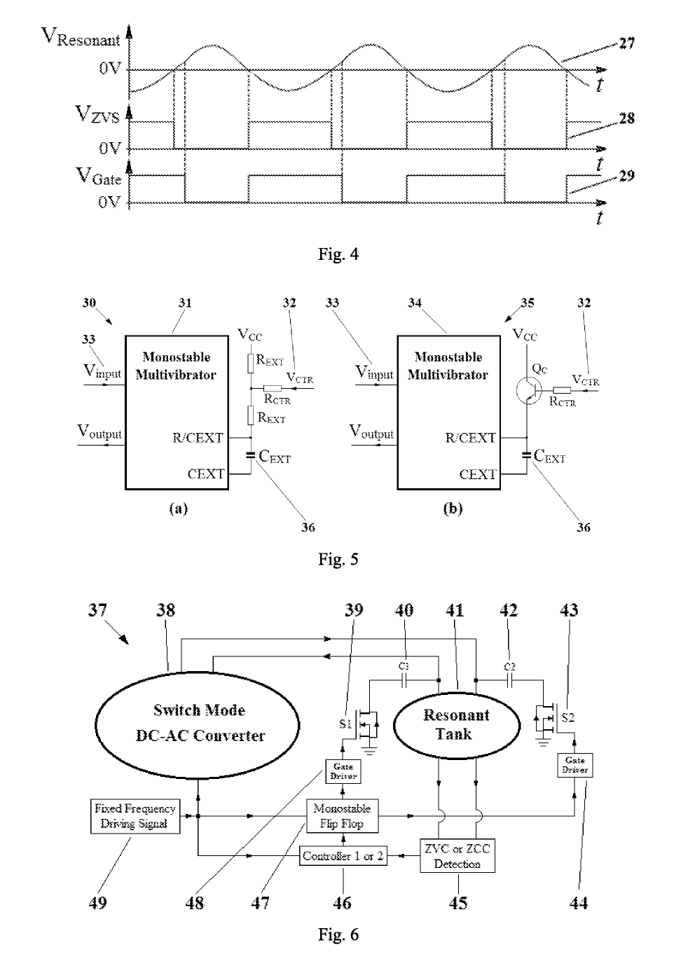

FIG. 4 shows the simulated waveforms of the VCSC, from which it can be seen that turning off of the switch S 25 (its gate driving signal is V_{gate} 29) does not have much influence and cause much EMI to the resonant voltage V_{Resonant} 27.

2.2 Methods to Generate the Controlling Signal for the VCSC

FIG. 5 shows some examples to generate the controlling signal for the VCSC by controlling the output pulse width of mono-stable multivabrators 31, 34 (or flip flops) with a DC voltage Vₑₜᵣ 2. The basic idea is to influence the charging/discharging process of the external capacitor C_{EXT} 36 of the mono-stable multivabritor 31, 34 with the control voltage 32 so that the output pulse width is adjusted.

It should be noted however that it is not the intention of the applicant to restrict or in any way limit the invention to the specific details. Those skilled in the art can find any number of variations, for example using digital means such as micro-controllers to realize the same function.

2.3 Application of the VCSC at the Primary Side of a WPT System to Compensate the Resonant Frequency of the System

FIG. 6 shows the strategy using the VCSC and Controller 1 or Controller 2 to form a fixed frequency and resonant WPT system 37. Different from the variable frequency systems introduced in Section 1.2 and Section 1.3, the output voltage of the controller 1 or 2 (46) here as shown in FIG. 6 is not used to change the output frequency of a VCO (8 or 18) but to change the output pulse width of a mono-stable flip flop 47 (or 24, 31, 34. Can also be realized through other means such as micro-controllers) which controls the conduction periods (therefore the average equivalent capacitance) of the two switch mode capacitors C 1 (40) and C2 (42). The ever-changing innate system resonant frequency is compensated by the variation of the two capacitors C1 and C2 and therefore remains constant, meaning that after compensation, the system resonant frequency always equals to the fixed system driving frequency 49, therefore a fixed frequency and resonant system is formed.

2.4 Application of the VCSC at the Secondary Side of a WPT System to Stabilize the Output Voltage by Tuning/Detuning

Besides being used at the primary side of a WPT system to compensate the system frequency, the VCSC can also be used at the secondary side of a WPT system (or similar systems such as switch mode power supplies, DC-DC converters) to adjust the output voltage through the effect of tuning/detuning. Section 2.4.1 and Section 2.4.2 present two different situations for this purpose when the secondary side circuit is parallel and serial tuned, respectively. It should be noted however that it is not the intention of the applicant to restrict or in any way limit the invention to the specific details. Those skilled in the art can find any number of variations, for example using a full bridge instead of half bridge regulation, adjusting the output voltage by changing the reference voltage V_{ref} of the PI controller in some way instead of simply making it constant, etc.

2.4.1 Parallel Tuning/Detuning

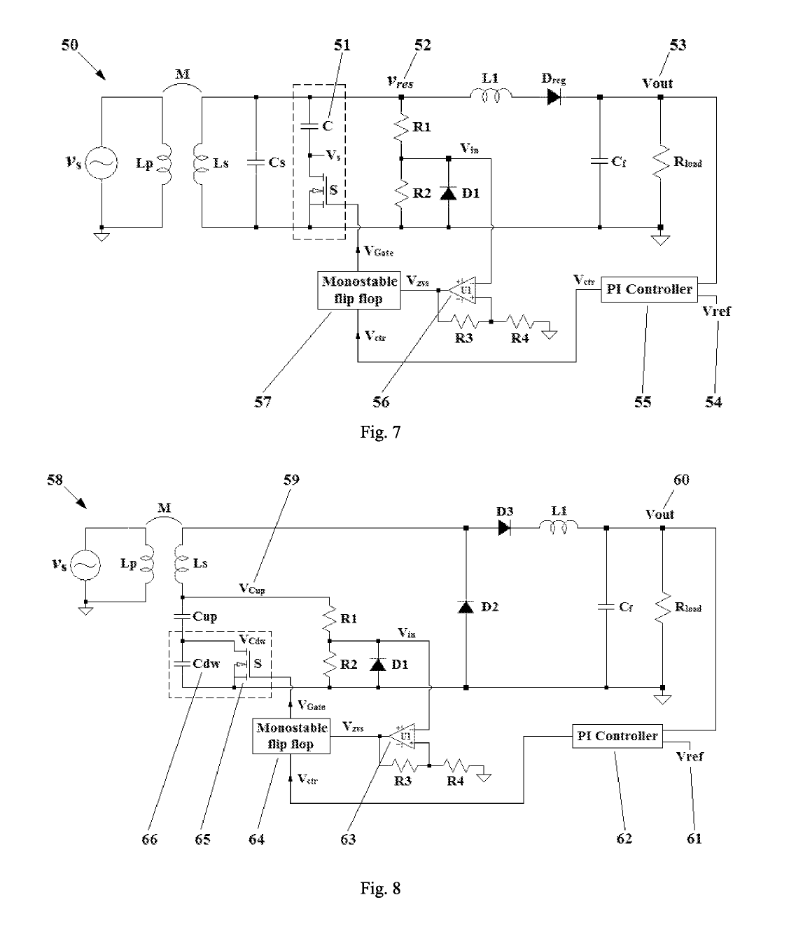

FIG. 7 shows an embodiment of the strategy to adjust or stabilize the output voltage of the secondary side of a WPT system (or any similar systems) through the tuning/detuning effect of the VCSC when it is used as a parallel tuning capacitor. It can be seen from FIG. 7 that a PI controller 55 is employed to generate the control voltage Vₑₜᵣ for the VCSC according to the fluctuation of the output voltage 53 so that the output voltage is made constant by the tuning/detuning effect of the VCSC as shown in the dashed block. Alternatively, instead of being made constant, the output voltage can also be adjusted by varying the value of the reference voltage V_{ref} 54 of the PI controller 55 in some way.

The U1 (56) in FIG. 7 is a comparator to detect the ZVC points of the resonant voltage Vᵣₑₛ 52, which is used to generate the rising edge for the gate driving signal V_{Gate} of the switch S through the mono-stable flip flop 57.

2.4.2 Serial Tuning/Detuning

Instead of being used as a parallel tuning capacitor, the VCSC can also be used as a serial tuning capacitor to adjust or stabilize the output voltage of the secondary side of a WPT system (or any similar systems) through the tuning/detuning effect as shown in FIG. 8. As can be seen, the switch S 65 here is in parallel with a capacitor C_{dw} 66 instead of connected in serial with a capacitor C 26 as shown in FIG. 3. So it should be noted that it is not the intention of the applicant to restrict or in any way limit the VCSC to the specific details as described in Section 2.1 and Section 2.2. Those skilled in the art can find any number of variations. The functions of the other parts of the circuit as shown in FIG. 8 are similar to those of their counterparts as shown in FIG. 7, so are not repeated here.

### 3. Multi-Transmitters High Power WPT Systems

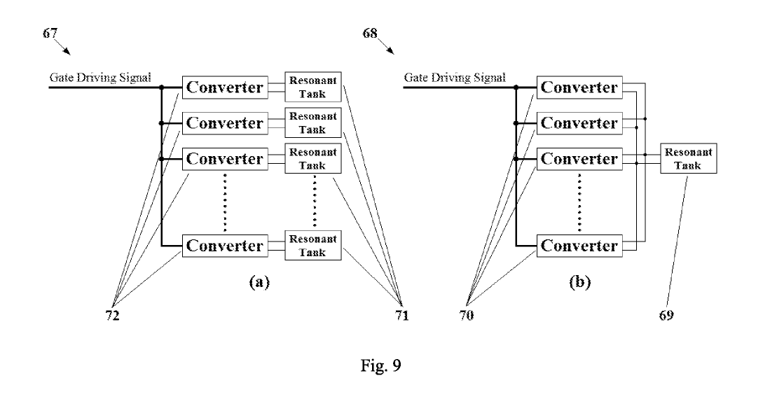

With the techniques presented in this patent available, the frequency and phase of WPT systems can be controlled in whatever the way as needed, and the system always works on “square wave driving, soft-switching and resonant” conditions at the same time. For example, the frequency and phase of the magnetic field generated by the primary coils in 69 or 71 of an IPT (Inductive Power Transfer) system can be controlled to be exactly the same although they may be generated by different DC-AC converters 70, 72 with the same 69 or different 71 resonant tanks. Consequently, these magnetic fields can be added together to drive the same secondary side circuits as shown in FIG. 9. In this way, high power systems can be realized with low power rating components because the power ratings of the components of separate primary side DC-AC converters 70, 72 can be low, however, the power transfer ability can be increased by using multi-primary side DC-AC converters working in parallel to drive the same secondary side circuit. Another advantage of this strategy is that the primary side “Multi-transmitters 70, 72” can be designed and manufactured in large scales as models so that the design and manufacture cost can be reduced. FIG. 9 (a) shows the strategy of different DC-AC converters 72 using different independent resonant tanks 71 but the frequency and phase of the oscillations in these resonant tanks can be controlled to be exactly the same so that they can be added together to drive the same secondary side circuit. FIG. 9 (b) shows the situation when different DC-AC converters 70 sharing the same resonant tank where the current injected into the resonant tank by different converters 70 need to be controlled to be exactly the same both in frequency and phase. Again, it should be noted that it is not the intention of the applicant to restrict or in any way limit the invention to the specific details as described in FIG. 9. Those skilled in the art can find any number of variations such as using this technique in any other WPT systems, switch mode power supplies, DC-DC converters, etc.

While the present inventions have been illustrated by the descriptions of the embodiments thereof, and while the embodiments have been described in detail, it is not the intention of the Applicant to restrict or in any way limit the scope of the appended claims to such details. Additional advantages and modifications will readily appear to those skilled in the art. Therefore, the invention in its broader aspects is not limited to the specific details, representative apparatus and methods, and illustrative examples shown and described. Accordingly, departures may be made from such details without departure from the spirit or scope of the Applicant's general inventive concept. Reference to any prior art in this specification does not constitute an admission that such prior art forms part of the common general knowledge.

1. A switch mode DC-AC converter driven oscillation system, comprising:
a primary and a secondary side circuit;
wherein:
the primary side circuit comprises a switch mode DC-AC converter, a primary side resonant tank, a VCO, a ZVC or ZCC detection module and a primary side controller;
the VCO generates a square wave which is used directly as a gate driving signal of the switch mode DC-AC converter without passing through any digital circuits;
a frequency of the gate driving signal generated by the VCO is a driving frequency of the system;
the driving frequency of the system is neither larger nor smaller than, but always equals to an innate resonant frequency of the system accurately at steady state;
the ZVC or ZCC detection module detects zero voltage or current crossing points of a voltage or current in the primary side resonant tank, and outputs a square wave representing the detected ZVC or ZCC points, which is input into the primary side controller;
the whole primary side circuit is of analog circuitry where there is no digital circuits of any kind;
the secondary side circuit comprises a secondary side resonant tank, a VCSC, a PI controller, a regulation circuit and load.

2. The switch mode DC-AC converter driven oscillation system in claim 1 wherein the primary side controller, further comprising:
a PC1 and a Low-pass Filter (LF);
wherein:
there are two input signals for PC1, one is from the ZVC or ZCC detection module and the other is the gate driving signal of the switch mode DC-AC converter;
an output signal of PC1 is input into the LF;
an output voltage of the LF is input into the VCO to control its output frequency;
the output frequency of the VCO is used directly as the gate driving signal of the switch mode DC-AC converter or the driving frequency of the system;
PC1 is a kind of phase comparator characterized in that no phase difference exists at locked condition, which means that the output voltage of the LF and therefore the output frequency of the VCO vary continuously until the two input signals of PC1 are equal in both phase and frequency;
as such, whenever the driving and innate resonant frequency of the system deviate from each other leading to the two input signals of PC1 are not equal in phase, the output voltage of the LF and therefore the output frequency of the VCO vary continuously to change the driving frequency of the system until the driving and innate resonant frequency of the system equal to each other so that the two input signals of PC1 become equal in both phase and frequency again meaning that the system regains its resonant and soft-switching condition.

3. The switch mode DC-AC converter driven oscillation system in claim 1 wherein the primary side controller as an alternative of claim 2, further comprising:
a PC2, a LF and a PI controller;
wherein:
there are two input signals for PC2, one is from the ZVC or ZCC detection module and the other is the gate driving signal of the switch mode DC-AC converter;
an output signal of PC2 is input into the LF;
an output voltage of the LF is input into the PI controller to compare with its reference voltage;
an output voltage of the PI controller is input into the VCO to control its output frequency;
the output frequency of the VCO is used directly as the gate driving signal of the switch mode DC-AC converter or the driving frequency of the system;
the PC2 is a kind of phase comparator characterized in that there exists a phase difference or phase error between its two input signals at locked condition, which means that the output voltage of the LF ITSELF does not vary CONTINUOUSLY until the two input signals of PC2 are equal in phase; to solve this problem, the PI controller is inserted between the LF and the VCO;
the reference voltage of the PI controller is adjusted to equal to the output voltage of the LF when the two input signals of PC2 are equal or at a preset fixed value in phase;
as such, when the two input signals of PC2 are not equal or not at the preset fixed value in phase meaning that the driving frequency of the system does not equal to the innate resonant frequency of the system, the output voltage of the LF does not equal to the reference voltage of the PI controller, which makes the output voltage of the PI controller and therefore the output frequency of the VCO vary CONTINUOUSLY to change the driving frequency of the system until the driving frequency of the system equals to the innate resonant frequency of the system so that the two input signals of PC2 become equal or at the preset fixed value in phase again meaning that the system regains its resonant and soft-switching condition.

4. The switch mode DC-AC converter driven oscillation system in claim 1 wherein the VCSC, further comprising:
a switch mode capacitor, a ZVS detection module and a mono-stable flip flop;
wherein:
the switch mode capacitor comprises a capacitor and a switch in series or parallel;
the switch is turned on when a resonant voltage across the capacitor is zero;
the switch is turned off when the resonant voltage across the capacitor is not zero;
an average equivalent capacitance of the switch mode capacitor is controlled by adjusting a conduction period of the switch or the capacitor;
an output pulse signal of the mono-stable flip flop is used as a gate driving signal of the switch;
the conduction period of the switch or the capacitor is controlled by an output pulse width of the output pulse signal of the mono-stable flip flop;
the output pulse width of the mono-stable flip flop is controlled by a voltage;
the ZVS detection module detects the resonant voltage across the capacitor and outputs a signal representing zero voltage crossing (ZVC) points of the resonant voltage across the capacitor;
an output signal from the ZVS detection module is used as a triggering signal for the mono-stable flip flop;
the switch of the switch mode capacitor is turned on by a leading edge of an output signal of the mono-stable flip flop;
as the triggering signal is from the ZVS detection module representing the ZVC points of the resonant voltage across the capacitor, the switch is turned on when the resonant voltage across the capacitor is zero.

5. The switch mode DC-AC converter driven oscillation system in claim 1 wherein the VCSC is configured to adjust an output voltage and power of the system, wherein:
the VCSC is connected as a parallel or serial tuning capacitor in the secondary side resonant tank;
an average equivalent capacitance of the VCSC is adjusted by a control voltage from the PI controller;
the PI controller monitors fluctuations of the output voltage of the system and outputs the control voltage to adjust the average equivalent capacitance of the VCSC for compensating the fluctuations of the output voltage of the system making it stabilized.
